(19) United States
(12) Patent Application Publication
(10) Pub. No.: US 2013/0093053 A1
(43) Pub. Date: Apr. 18, 2013

(54) TRENCH TYPE PIP CAPACITOR, POWER INTEGRATED CIRCUIT DEVICE USING THE CAPACITOR, AND METHOD OF MANUFACTURING THE POWER INTEGRATED CIRCUIT DEVICE

(71) Applicant: FUJI ELECTRIC CO., LTD., Kawasaki-shi (JP)

(72) Inventors: Yoshiaki TOYODA, Matsumoto-city (JP); Takatoshi OOE, Matsumoto-city (JP); Masanobu IWAYA, Matsumoto-city (JP)

(73) Assignee: FUJI ELECTRIC CO., LTD., Kawasaki-shi (JP)

(21) Appl. No.: 13/648,713

(22) Filed: Oct. 10, 2012

(30) Foreign Application Priority Data
Oct. 18, 2011 (JP) 2011-228961

(51) Int. Cl. H01L 29/92; H01L 21/02

(52) U.S. Cl. 257/535; 438/386; 257/E29.343; 257/E21.011

(57) ABSTRACT

A trench-type PIP capacitor having a small step at the end part of the capacitor without increasing manufacturing cost, and a power integrated circuit device that uses such a trench-type PIP capacitor are disclosed. A method of manufacturing the power integrated circuit device also is disclosed. A trench-type PIP capacitor has a construction, in the surface region of a semiconductor substrate, comprising an isolating insulation layer formed on an inner wall of a trench and a first polysilicon that fills the trench through the isolating insulation layer and becomes a lower electrode. Since this construction has a small step formed at the end region of the capacitor, a metal layer for wiring does not need to be made excessively thick, allowing a fine structure of the metal layer. Therefore, the power IC provided with such a trench-type PIP capacitor can have a fine structure.

This application is based on, and claims priority to, Japanese Patent Application No. 2011-228961, filed on Oct. 18, 2011, the contents of which are incorporated herein by reference.

### BACKGROUND OF THE INVENTION

A. Field of the Invention

The present invention relates to a capacitance element of a polysilicon (P)-insulator (I)-polysilicon (P) type having a trench structure (hereinafter referred to as a trench-type PIP capacitor) and a power integrated circuit device (hereinafter also referred to as a power IC) having the trench-type PIP capacitor. The invention relates also to a method of manufacturing the power IC.

B. Description of the Related Art

In order to achieve a low ON resistance semiconductor element with a small area, a trench gate type semiconductor element with a gate region formed on a trench has been proposed. To improve reliability and enhance breakdown voltage of this trench gate type semiconductor element at a low cost, a power semiconductor device called a trench gate type power IC has been developed comprising semiconductor elements for controlling and protecting the trench gate type semiconductor elements formed on one and the same semiconductor substrate. The trench gate type power IC is a power IC having a vertical power MOSFET with a trench gate structure. The vertical power MOSFET can be replaced by a vertical insulated gate bipolar transistor (IGBT) in some cases.

FIG. 9 is a sectional view of an essential part of a conventional trench gate type power IC having MOS capacitor 22b formed on one and the same semiconductor substrate.

The trench gate type power IC comprises an output stage semiconductor element of a vertical power MOSFET 21 with a trench gate structure and controlling semiconductor elements of a low voltage lateral MOSFET 22a with a planar gate structure and a MOS type capacitance element of a MOS capacitor 22b.

Vertical power MOSFET 21 with a trench gate structure, lateral MOSFET 22a with a planar gate structure, and MOS capacitor 22b are formed on a single substrate that is a lamination of n⁺ type semiconductor layer 2 and n⁻ type epitaxial layer 3. An ordinary power IC has electric circuits for controlling the output stage semiconductor element. The electric circuits include a delay circuit, a filter circuit, and an oscillator circuit. Multiple MOS capacitors 22b are used for constructing those electric circuits. The symbols 12d and 12e in FIG. 9 designate metal layers for electrodes of MOS capacitor 22b.

FIG. 10 is a sectional view of an essential part of a conventional trench gate type power IC having a trench gate type power MOSFET element with planar-type PIP capacitor 22c formed on one and the same semiconductor substrate. This power IC is disclosed in Japanese Unexamined Patent Application Publication No. 2003-264289. Japanese Unexamined Patent Application Publication No. 2003-282720 discloses an example of a planar-type PIP capacitor applied to a semiconductor device.

The variation of the capacitance value corresponding to the applied voltage between electrodes is smaller in planar-type PIP capacitor 22c than in MOS capacitor 22b. The electrodes to which a voltage is applied in planar-type PIP capacitor 22c are made of highly doped polysilicon 14 and 6c, and the voltage is held with capacitive insulation layer 15 sandwiched with polysilicon 14 and 6c. In this structure, a space charge region is formed in capacitive insulation layer 15 and scarcely formed in the electrodes of polysilicon 14 and 6c. As a result, the space charge layer width does not depend on the applied voltage, although it does depend on the thickness of capacitive insulation layer 15. Therefore, the capacitance value of planar-type PIP capacitor 22c varies little with the applied voltage.

Electrodes of MOS capacitor 22b shown in FIG. 9 are a metal, which is highly doped polysilicon 6c, and a semiconductor layer 16. The applied voltage is held by capacitive insulation layer 7c, which is an oxide film, and semiconductor layer 16. Since the width of the depletion layer formed in semiconductor layer 16 varies (in the case of the semiconductor layer of an n-type semiconductor layer), the width of the space charge layer formed in capacitive insulator layer 7c and semiconductor layer 16 changes. Therefore, the capacitance value of MOS capacitor 22b changes greatly depending on the applied voltage.

In the case of the lower electrode of n-type semiconductor layer 16, when the voltage applied on the upper electrode is low with respect to n-type semiconductor layer 16, the width of the depletion layer expands, thereby decreasing capacitance value. Therefore, circuit design, for example, design of capacitance value of MOS capacitor 22b, needs to take this lowered capacitance value into consideration.

Planar-type PIP capacitor 22c exhibiting a small voltage dependence is applied to circuits that need a large capacitance value and circuits that require a capacitance value with high precision and little variation. Planar-type PIP capacitor 22c, being electrically insulated from the semiconductor substrate with thick oxide film 11a (a LOCOS), can favorably be used with less restriction to the voltage that is applied to the upper and lower electrodes as compared with MOS capacitor 2b in FIG. 9.

FIG. 11A is a circuit diagram of a high-side-type power IC using an output stage as a high-side element, and FIG. 11B shows a load to be connected to the output terminal of the power IC of FIG. 11A. This high-side type power IC 101 is composed of control circuit 107 and output stage semiconductor element 102, which is a power MOSFET, for example. Control circuit 107 includes logic circuit 111, driving circuit 112, and protecting circuit 113. Driving circuit 112 provides a gate signal for power MOSFET 102 of an output stage semiconductor element. Output terminal 105 of the power IC 101 is connected to the inductor L of a load. Reference numeral 103 in FIG. 11A designates the power supply terminal of control circuit 107, reference numeral 104 designates the input terminal of control circuit 107, and reference numeral 106 designates the ground terminal.

In the high-side-type power IC 101, the gate voltage of output stage semiconductor element 102 is set to be higher than the drain voltage, which is the voltage at power supply terminal 103, in order to achieve sufficient current-carrying capability. Accordingly, the power supply voltage of driving circuit 112 to generate the gate voltage needs to be elevated over the voltage of power supply terminal 103 of control circuit 107. To achieve such a condition, driving circuit 112 often uses a charge pumping circuit.

FIG. 12 is a circuit diagram of a charge pumping circuit. Charge pumping circuit 120 comprises two capacitors C of a large capacitance, and five switches, SW1 through SW5. In operation of charge pumping circuit 120, the switches SW1 through SW4 are first closed to determine the voltage of the two parallel-connected capacitors C, C at the voltage given to the input terminal IN. Then, the switches SW1 through SW4 are opened and the switch SW5 is closed to connect the two capacitors C, C in series. Thus, two times the capacitor voltage is delivered from the output terminal OUT. The use of charge pumping circuit 120 can drive output stage semiconductor element 102 of a power MOSFET at a gate voltage higher than the drain voltage. The capacitors, C, C of charge pumping circuit 120, becoming a power supply of driving circuit 112, need a large capacitance and high precision with little voltage dependence. Accordingly, planar-type PIP capacitors 22c often are used.

Power IC 101 is desired to install a larger scale of control circuit than traditional ones to control the output stage semiconductor element with higher performance. In order to meet the requirement, efforts are in progress to make the control circuit 107 of power IC 101 finer and more precise, and to attain the overall circuit down-sizing. Recently, demand for cost-reduction and further down-sizing is significantly rising.

The following are documents disclosing power integrated circuit devices (power ICs).

Japanese Unexamined Patent Application Publication No. H06-151728 discloses a power IC in which a semiconductor substrate comprises an n⁺-type base body, an n⁻-type epitaxial layer formed thereon, and a p-type epitaxial layer formed on the n⁻-type epitaxial layer. The power IC has a power MOSFET that carries electric current from a first principal surface to a second principal surface of the semiconductor substrate, and a control element formed on the first principal surface side of the semiconductor substrate. The power MOSFET and the control element are isolated with a first trench.

A channel region of the MOSFET is formed on the side wall of a second trench in the p-type epitaxial layer. According to the document, this construction facilitates trench isolation between the power MOSFET for carrying an electric current from the first principal surface to the second principal surface of the semiconductor substrate and the control element formed on the first principal surface side of the semiconductor substrate.

Japanese Unexamined Patent Application Publication No. 2000-022140 discloses a semiconductor device installing a lateral power MOSFET provided with a trench disposed at a place that does not interfere with the operation current flow between a drain region formed in the active substrate and a potential lead-out region to be connected to the drain region. A gate electrode is embedded in the trench.

The trench and the gate electrode are disposed at both sides of a source region. The potential lead-out regions are disposed at both sides of another region. The trench of the lateral power MOSFET and the trench in the element-isolating region are formed with the same structure and in the same manufacturing step. The document asserts that the construction allows manufacturing a semiconductor device having an element-isolating region using a trench and a transistor using a trench with a small number of steps.

Japanese Unexamined Patent Application Publication No. 2003-264289 discloses a semiconductor device in which polycrystalline silicon gate layers are formed in and out of trenches formed on the principal surface of a semiconductor layer of a semiconductor substrate. The polycrystalline silicon gate layers are formed through a gate insulating film and connected to a gate electrode. A polycrystalline silicon diode is formed on the principal surface of the semiconductor layer through an insulating film. The film thickness of the polycrystalline silicone layer of the polycrystalline diode is thinner than the film thickness of the polycrystalline silicon layer of the polysilicon gate layer. According to the document this configuration improves performance of a semiconductor device even having a construction with a trench-type insulated gate semiconductor element and a polycrystalline silicon diode formed on the same chip.

Japanese Unexamined Patent Application Publication No. H08-102539 discloses a power integrated circuit including a power MOSFET and a control circuit on the same chip to which an npn transistor is added. The npn transistor is combined between a p well containing components of the power integrated circuit and the n-type substrate, and turns ON in response to the forward bias of the body diode of the power MOSFET.

In this power IC, a depletion mode controlled MOSFET transistor is combined to the gate of the power MOSFET through a fault-latch circuit, and connected to a capacitor in series. The node between the gate of the power MOSFET and the capacitor is isolated from the n-type substrate when the npn transistor turns ON and the power MOSFET turns OFF. According to the document this technique provides a power MOSFET exhibiting high reliability against overcurrent and overheating.

Japanese Unexamined Patent Application Publication No. 2009-260271 discloses a semiconductor device and a DC to DC converter using the semiconductor device. The semiconductor device comprises a trench formed in a MOSFET region and a trench gate electrode embedded in the trench. Another trench is formed in a capacitor region and a trench source electrode is embedded in the trench. The trench source electrode has the shape of a stripe, a part of which is connected to the source electrode. According to the document this construction suppresses surge of the source-drain voltage at the time of turning OFF.

Japanese Unexamined Patent Application Publication No. 2003-282720 discloses a semiconductor device having a capacitor that comprises a first conductive layer, a second conductive layer formed above the first conductive layer, and a capacitive insulation layer formed between the first and the second conductive layers. The first conductive layer and the second conductive layer each include a metal layer. The first conductive layer is provided with a first connecting part. A first contact is formed above the first connecting part. The second conductive layer is provided with a second connecting part. A second contact is formed above the second connecting part. The second contact is formed in a region excepting the region above the first conductive layer. The first and second conductive layers are formed of polysilicon to construct a planar-type PIP capacitor. This construction provides, according to the assertion of the document, a capacitive insulation layer exhibiting a stable film quality.

In order to achieve cost reduction and down-sizing in the power IC including a multiple of planar-type PIP capacitor 22c as shown in FIG. 10, the fine structure of the circuit must be achieved as described previously.

However, in the fine structure of planar-type PIP capacitor 22c, having a laminated structure with polysilicon electrodes 6c and 14 sandwiching capacitive insulation layer 15, step 31a is generated between end part 31 of planar-type PIP capacitor 22c and the surroundings as shown in FIG. 10.

If step 31a is large, metal layer 12e, which is a metallic wiring connecting circuit components over step 31a, may break. If metal layer 12e is made thicker to avoid the breakage, micromachining of metal layer 12e becomes difficult.

Step 31a of planar-type PIP capacitor 22c has a thickness dimension of the sum of the thicknesses of polysilicon 6c of the lower electrode, capacitive insulation layer 15, and polysilicon 14 of the upper electrode. Thus, step 31a is large and presents an obstacle to micromachining.

In order to decrease step 31a at end part 31 of planar-type PIP capacitor 22c, various means can be taken. For example, step 31a can be made insignificant by increasing the thickness of interlayer dielectric film 13b laminated on planar-type PIP capacitor 22c or interlayer dielectric film 13b with an increased thickness can be flattened by means of a chemical mechanical polishing method (a CMP method). These methods, however, increase both manufacturing lead time and production cost.

The present invention is directed to overcoming or at least reducing the effects of one or more of the problems set forth above.

### SUMMARY OF THE INVENTION

The present invention solves the above-described problems, and provides a PIP capacitor having a small step at the capacitor end without increasing manufacturing cost, and a power integrated circuit device using the PIP capacitor. The invention also provides a method of manufacturing the power integrated circuit device.

A trench-type PIP capacitor according to the invention comprises a trench that is formed from a surface of a semiconductor layer toward an inner part of the semiconductor layer. An isolating insulation layer is formed on an inner wall of the trench and electrically isolates a first polysilicon from the semiconductor layer. The first polysilicon fills the trench through the isolating insulation layer and becomes a lower electrode. A capacitive insulation layer is formed on the first polysilicon and becomes a capacitance element of the capacitor. A second polysilicon that is formed on the capacitive insulation layer becomes an upper electrode. Preferably, the height of the surface of the first polysilicon is substantially equal to the height of the surface of the semiconductor layer.

A power integrated circuit device comprises the trench-type PIP capacitor defined above, an output stage element that passes or interrupts main current, and a control circuit for controlling the output stage element, the latter two components being formed on one and the same semiconductor layer as that on which the trench-type PIP capacitor is formed.

In the power integrated circuit device according to the invention, a well region of a conductivity type different from that of the semiconductor layer preferably is formed selectively in the surface region of the semiconductor layer, and the trench-type PIP capacitor is formed in the well region. Also it is preferable that a well region of a conductivity type different from that of the semiconductor layer is formed selectively in the surface region of the semiconductor layer, and the trench-type PIP capacitor is formed passing through the well region. Preferably the well region is a diffusion layer, and the semiconductor layer is an epitaxial layer formed on a semiconductor base material that has an impurity concentration higher than that of the semiconductor layer.

In a preferred embodiment the control circuit of the integrated circuit device includes a charge pumping circuit that uses the trench-type PIP capacitor for a capacitor in the charge pumping circuit. The output stage element preferably is a vertical power MOS semiconductor element with a trench gate structure or a planar gate structure. Preferably the height of the surface of the second polysilicon is substantially equal to the height of the surface of the semiconductor layer.

In a method of manufacturing a power integrated circuit device according to the invention, the trench to be filled with the first polysilicon is formed simultaneously with a trench to deposit a gate of the vertical power MOS semiconductor element with the trench gate structure. Preferably the capacitive insulation layer is a silicon oxide film formed by a chemical vapor deposition (CVD) method.

A trench-type PIP capacitor according to the invention comprises an insulation layer formed on the inner wall of a trench and a lower electrode of polysilicon embedded in the trench through the insulation layer. This construction decreases the step formed at an end part of the capacitor. As a result, the thickness of the metal layer for wiring does not need to be increased, and therefore the metal layer can have a fine structure.

When the surface height of the lower electrode of polysilicon is made substantially equal to the surface height of the semiconductor substrate according to the invention, the step at the end part of the capacitor is decreased without increasing the thickness of the interlayer dielectric film disposed on the upper electrode of polysilicon and without performing a flattening treatment by means of the CMP method. Therefore, increase of manufacturing cost is avoided. Thus, use of the trench-type PIP capacitor of the invention allows a power integrated circuit device (a power IC) to have a fine structure without increase in manufacturing cost.

When an insulation layer that is a capacitance element is formed with a silicon dioxide film by means of a CVD method according to the invention, this process facilitates integration with other general IC-manufacturing processes. This process does not add a thermal history, which might vary characteristics of semiconductor elements composing the control circuit.

### BRIEF DESCRIPTION OF THE DRAWINGS

The foregoing advantages and features of the invention will become apparent upon reference to the following detailed description and the accompanying drawings, of which:

FIGS. 1A and 1B show a construction of a trench-type PIP capacitor of a first embodiment according to the present invention in the vicinity of the capacitor, in which FIG. 1A is a plan view of an essential part and FIG. 1B is a sectional view of the essential part cut along the line X-X in FIG. 1A;

FIG. 2 is a sectional view of an essential part of a trench-type PIP capacitor of a second embodiment according to the present invention in the vicinity of the capacitor;

FIG. 3 is a sectional view of an essential part of a trench-type PIP capacitor of a third embodiment according to the present invention in the vicinity of the capacitor;

FIG. 4 is a sectional view of an essential part of a trench-type PIP capacitor of a fourth embodiment according to the present invention in the vicinity of the capacitor;

FIG. 5 is a sectional view of an essential part of a power integrated circuit device of a fifth embodiment according to the present invention;

FIG. 6 is a sectional view of an essential part of a power integrated circuit device of a sixth embodiment according to the present invention;

FIG. 7 is a sectional view of an essential part of a power integrated circuit device of a seventh embodiment according to the present invention;

FIG. 8 is a sectional view of an essential part of a power integrated circuit device of an eighth embodiment according to the present invention;

FIG. 9 is a sectional view of an essential part of a conventional trench gate type power IC having a trench gate type power MOSFET element with a MOS capacitor formed on one and the same semiconductor substrate;

FIG. 10 is a sectional view of an essential part of a conventional trench gate type power IC having a trench gate type power MOSFET element with a planar-type PIP capacitor formed on one and the same semiconductor substrate;

FIG. 11A shows a circuit construction of a high-side type power IC using an output stage of a high-side element, and FIG. 11B shows a load connected to the output terminal of the power IC; and

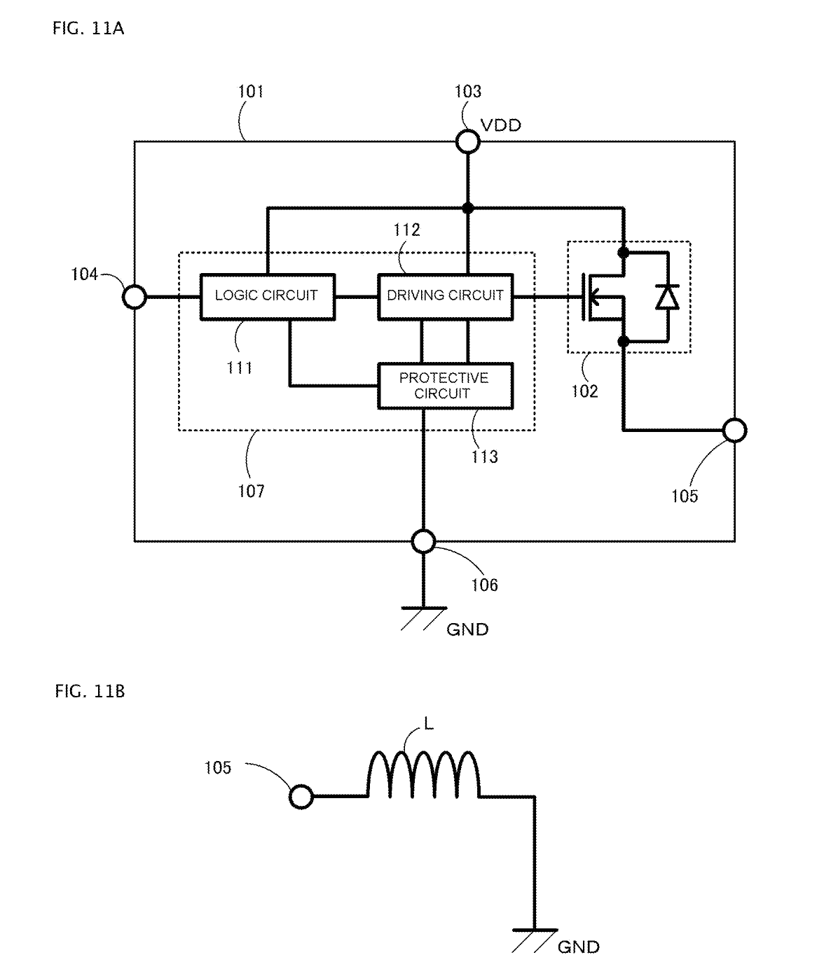

FIG. 12 is a circuit diagram of a charge pumping circuit.

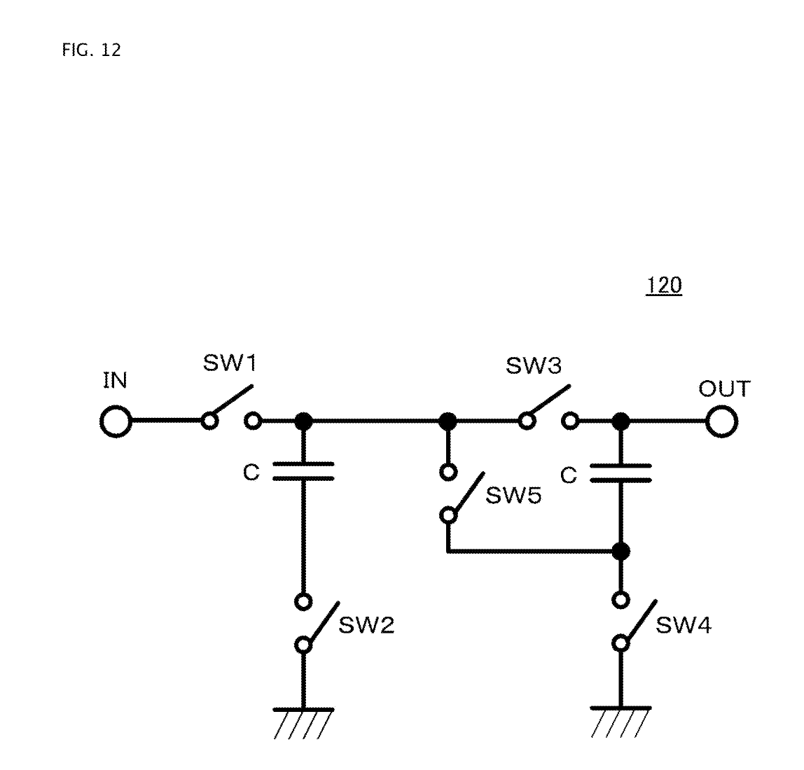

### DETAILED DESCRIPTION OF SPECIFIC EMBODIMENTS

Some preferred embodiments of the invention will be described in the following. In the description below, a first conductivity type is the n type and a second conductivity type is the p type, although the conductivity type can be reversed. A trench used in a trench-type PIP capacitor of the invention is formed in order to decrease the step at the end part of the capacitor. A trench in the invention does not use an insulation layer on the inner wall of the trench for obtaining a large capacitance element like a trench in known trench type MOS gate. “A trench-type PIP capacitor” referred to in this specification is a polysilicon-insulator-polysilicon (PIP) capacitor that comprises a lower electrode of polysilicon embedded in (or filling) a trench, an insulation layer formed on the lower electrode, and an upper electrode of a conductive film of polysilicon formed on the insulation layer to form a sandwich structure. Similar parts to the conventional ones are given the same symbols in the following description and the referenced drawings.

### First Embodiment

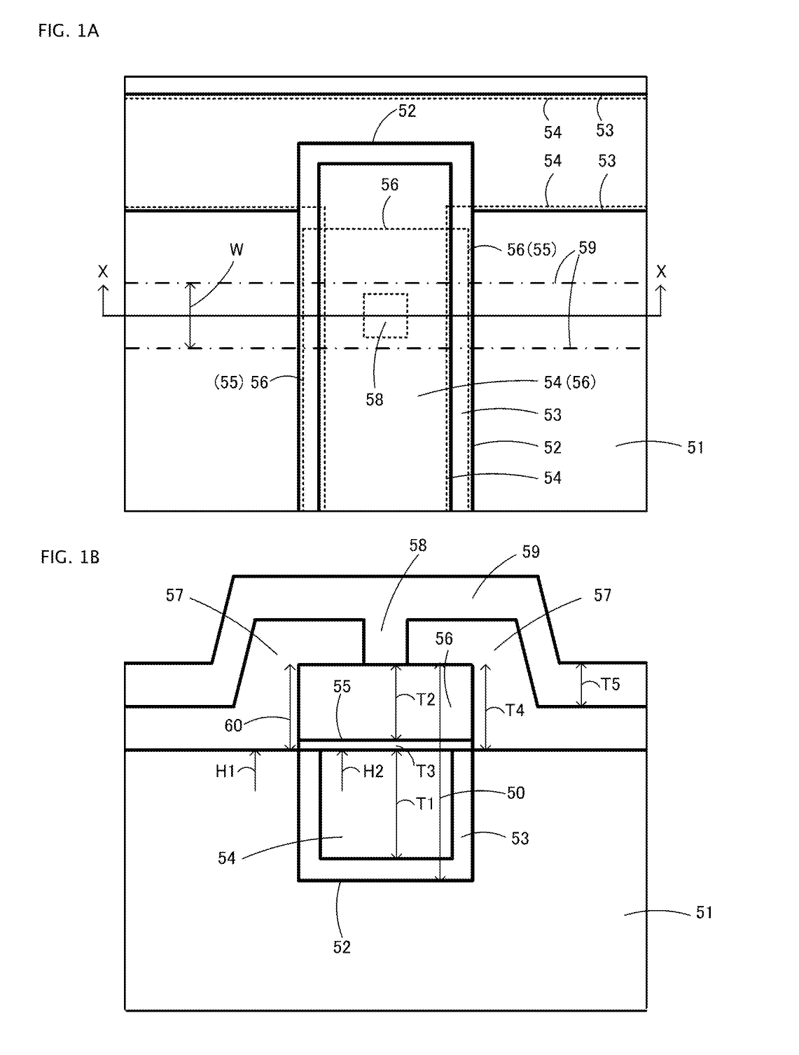

FIGS. 1A and 1B show a construction of a trench-type PIP capacitor 50, including the surroundings, of a first embodiment according to the invention, in which FIG. 1A is a plan view of an essential part and FIG. 1B is a sectional view cut along the line X-X in FIG. 1A. The trench-type PIP capacitor 50 of FIG. 1 is a part of a power IC including a vertical power MOSFET, for example (not shown in the figure), on the same semiconductor substrate.

Trench-type PIP capacitor 50 has a characteristic structure as described below. Trench 52 is formed in semiconductor substrate 51. Isolating insulation layer 53 is formed on the inner wall of trench 52 to isolate electrically first polysilicon 54 from semiconductor substrate 51. First polysilicon 54 is embedded in the trench through isolating insulation layer 53 to form a lower electrode. Capacitive insulation layer 55 is formed as a capacitance element on first polysilicon 54. An upper electrode of second polysilicon 56 is formed on capacitive insulation layer 55. Thus, trench-type PIP capacitor 50 is constructed. First polysilicon 54 and second polysilicon 56 are polycrystalline silicon layers.

First polysilicon 54 of the lower electrode extends along the trench 52 and leads out along the end part of the side wall of the trench to the surface as shown in FIG. 1A. The lower electrode is connected to a metal layer (not shown in the figure), which in turn is connected electrically to a semiconductor element. The metal layer is aluminum containing minute additive of silicon (Al—Si) or copper.

The height H2 of the surface of first polysilicon 54 is substantially equal to the height H1 of the surface of semiconductor substrate 41. Step 60 at the end of the trench-type PIP capacitor 50 in this configuration is equal to the sum T4 of the thickness T3 of capacitive insulation layer 55 and the thickness T2 of second polysilicon 56. The height H1 of the surface of first polysilicon 54 and the height H2 of the surface of semiconductor substrate 51 are measured from a common reference level. The common reference level can be a bottom plane of semiconductor substrate 51, for example.

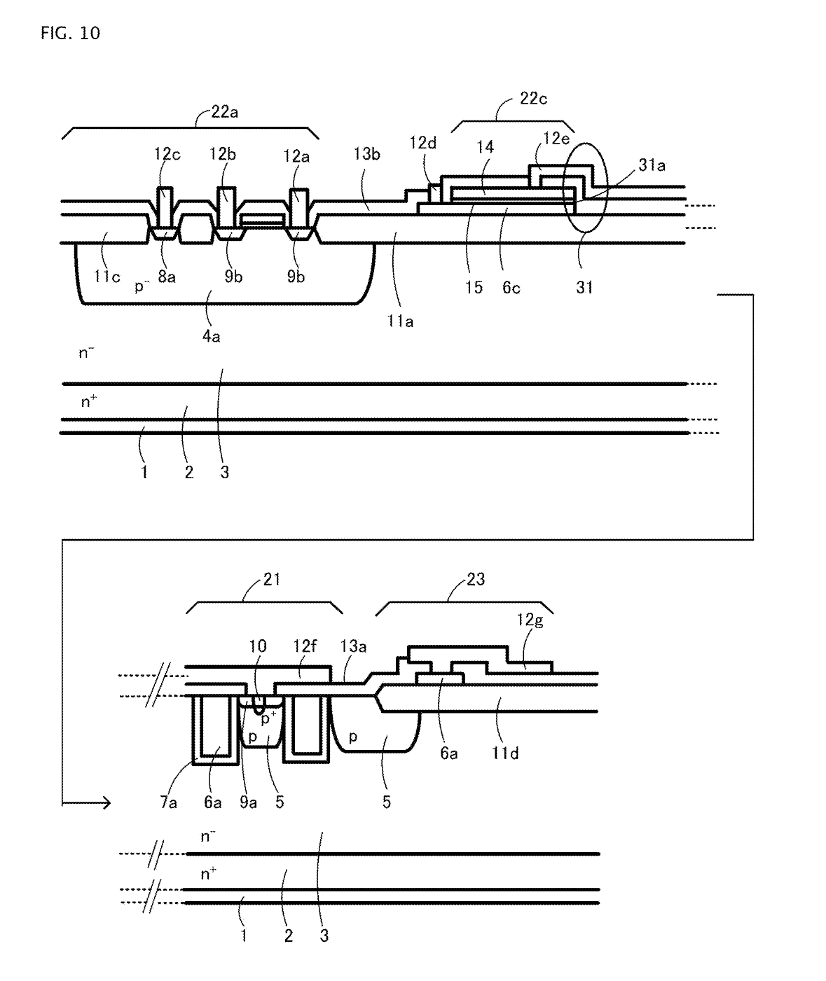

Step 60 of trench-type PIP capacitor 50 is smaller than step 31a at end part 31 of traditional planar-type PIP capacitor 22c shown in FIG. 10 by the thickness of polysilicon 6c. This structure allows a reduced thickness T5 of metal layer 59 connected to second polysilicon 56 through contact hole 58 formed in interlayer dielectric film 57. The width W of metal layer 59 can also be made thin. Thus, fine structure of metal layer 59 allows fine construction of electric circuit of the power IC.

Because step 60 is decreased without increasing the thickness of interlayer dielectric film 57 and without flattening interlayer dielectric film 57 by means of the CMP method, production cost is suppressed.

In application of trench-type PIP capacitor 50 to a power IC, trench 52 of trench-type PIP capacitor 50 can be formed simultaneously with the trench of a trench gate type vertical power MOSFET composing the power IC.

### Second Embodiment

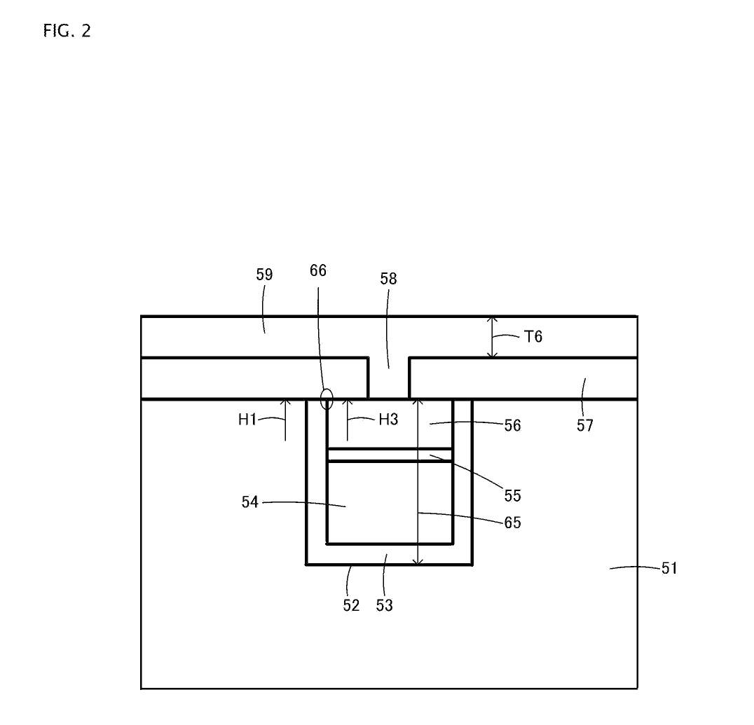

FIG. 2 is a sectional view of an essential part of trench-type PIP capacitor 65, including the surroundings, of a second embodiment according to the present invention. FIG. 2 corresponds to the sectional view of FIG. 1B. A plan view of PIP capacitor 65, though not given, is similar to FIG. 1A.

Trench-type PIP capacitor 65 of FIG. 2 is different from the trench-type PIP capacitor of FIG. 1A in that the upper electrode of second polysilicon 56 of the trench-type PIP capacitor 65 also is formed within trench 52. Thus, the surface height H3 of second polysilicon 56 is made substantially equal to the surface height H1 of semiconductor substrate 51, to completely eliminate the step.

Trench-type PIP capacitor 65 of the second embodiment comprises isolating insulation layer 53 formed on the inner wall of trench 52, a lower electrode of first polysilicon 54 formed in the trench through isolating insulation layer 53, capacitive insulation layer 55 formed on first polysilicon 54, and an upper electrode of second polysilicon 56 formed on capacitive insulation layer 55. The surface height H3 of second polysilicon 56 is made substantially equal to the surface height H1 of semiconductor substrate 51.

Because the step at end part 66 of the trench-type PIP capacitor 65 is eliminated, the thickness T6 of metal layer 59 for wiring is thinner than the thickness T5 of metal layer 59 in trench-type PIP capacitor 60 of FIG. 1B. Accordingly, metal layer 59 can be finer than the one in the structure of FIG. 1B, and an IC of fine structure is obtained.

### Third Embodiment

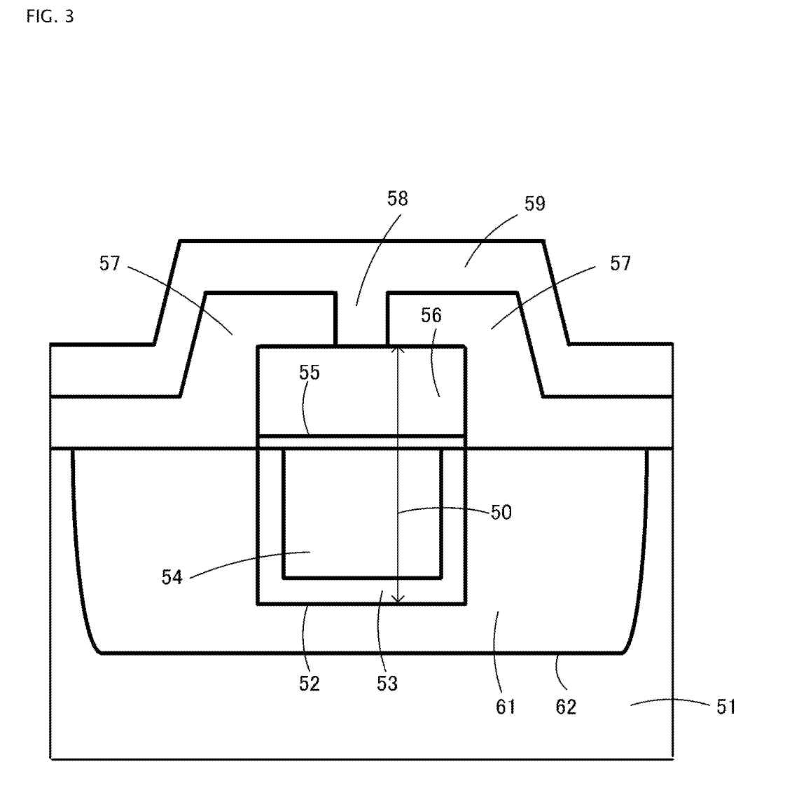

FIG. 3 is a sectional view of an essential part of trench-type PIP capacitor 50, including the surroundings, of a third embodiment according to the invention. Trench-type PIP capacitor 50 of FIG. 3 is different from the trench-type PIP capacitor of FIGS. 1A and 1B in that trench 52 is formed in a surface region of diffusion layer 61 of a conductivity type opposite to that of semiconductor substrate 51. When a high voltage is applied between semiconductor substrate 51 and first polysilicon 54, the voltage is held partly with pn junction 62 formed between semiconductor substrate 51 and diffusion layer 61. Consequently, voltage across isolating insulation layer 53 is reduced to avoid dielectric breakdown of isolating insulation layer 53.

Diffusion layer 61 can be formed in trench-type PIP capacitor 65 of the second embodiment to reduce the voltage across isolating insulation layer 53, although no drawing is given.

### Fourth Embodiment

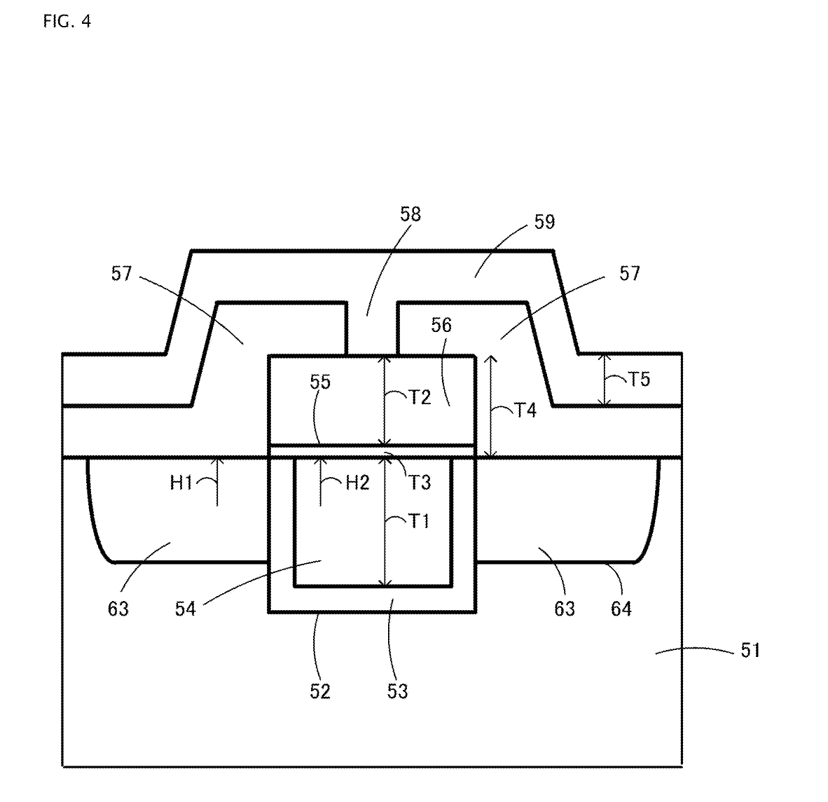

FIG. 4 is a sectional view of a trench-type PIP capacitor, including the surroundings, of the fourth embodiment according to the invention. The trench-type PIP capacitor of the fourth embodiment differs from the capacitor of the third embodiment shown in FIG. 3 in that trench 52 in the fourth embodiment is formed passing through diffusion layer 63. When a high voltage is applied between semiconductor substrate 51 and first polysilicon 54, the voltage is partly held with pn junction 64 formed between semiconductor substrate 51 and diffusion layer 63. Consequently, electric voltage across isolating insulation layer 53 is reduced to avoid dielectric breakdown of isolating insulation layer 53. As compared with the construction of the third embodiment, the construction of the fourth embodiment bears a smaller voltage with pn junction 64 formed between semiconductor substrate 51 and diffusion layer 63, somewhat deteriorating the performance to avoid dielectric breakdown of isolating insulation layer 53, as compared with the third embodiment.

Diffusion layer 63 can be formed in trench-type PIP capacitor 65 of the second embodiment to reduce the voltage across isolating insulation layer 53, although no drawing is given.

### Fifth Embodiment

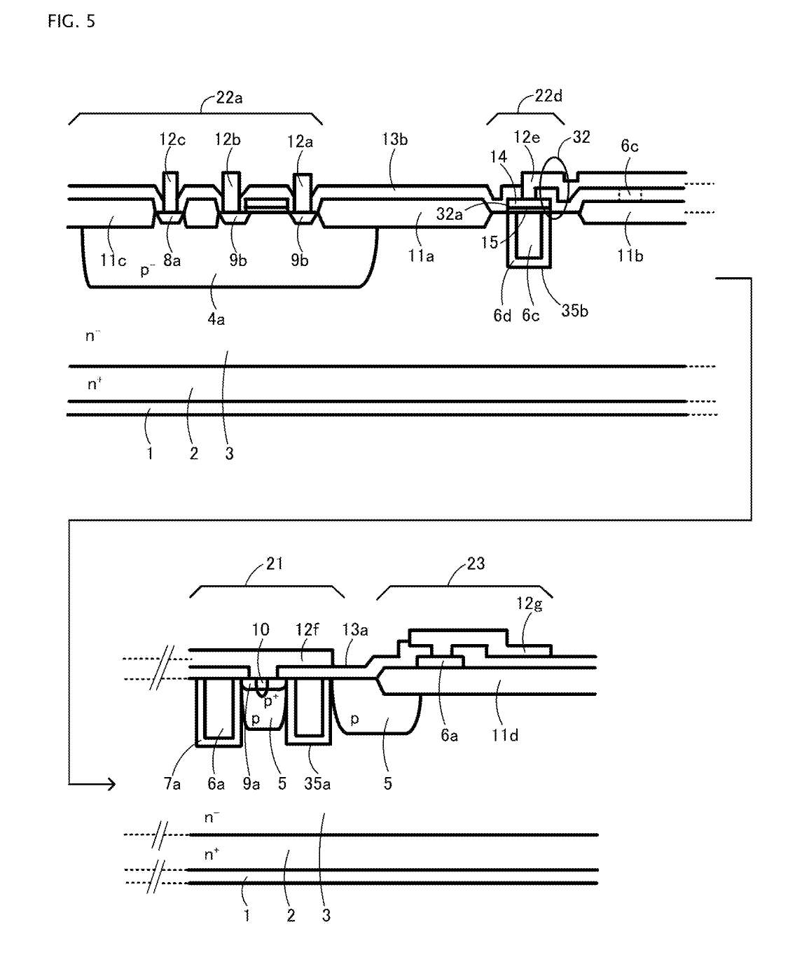

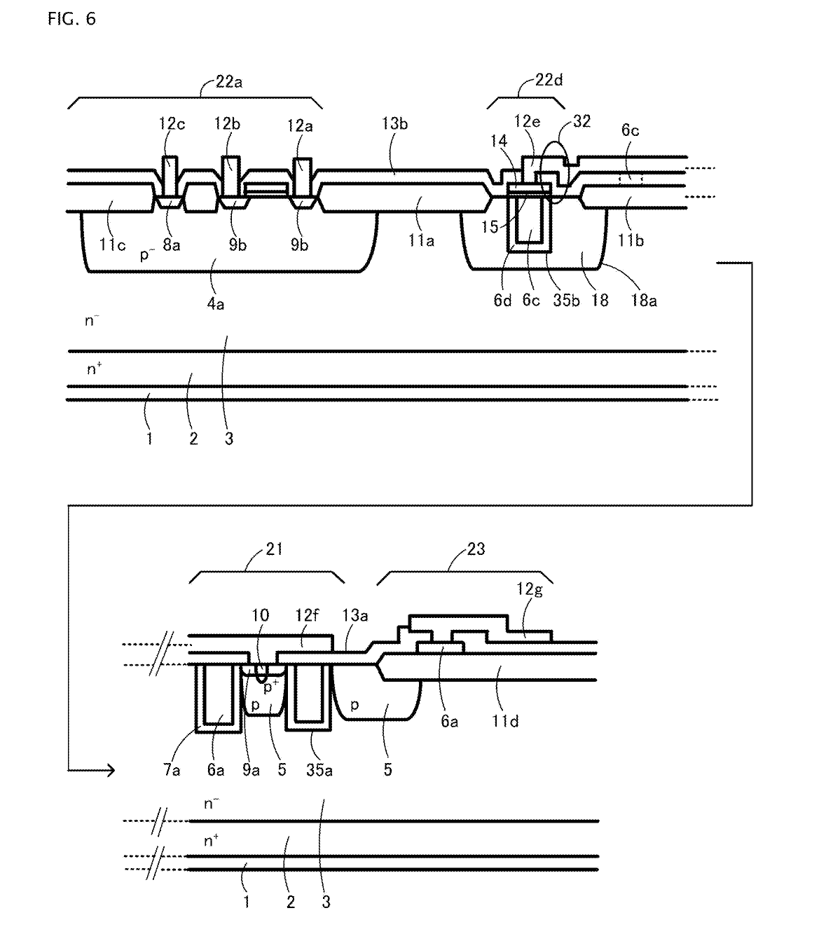

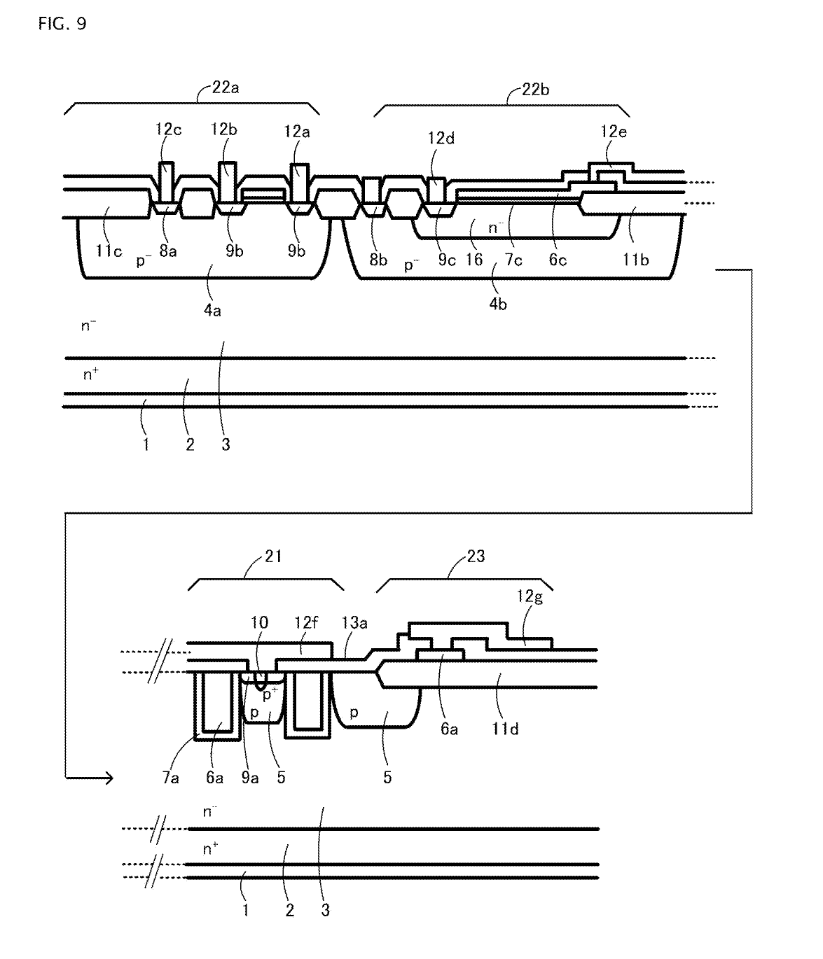

FIG. 5 is a sectional view of an essential part of a power integrated circuit device of a fifth embodiment according to the invention. This integrated circuit device is a power IC having vertical MOSFET 21 with a trench gate structure and trench-type PIP capacitor 22d that are formed in one and the same semiconductor substrate. Vertical MOSFET 21 with a trench gate structure can be replaced by another vertical power MOS element such as a vertical IGBT. The construction of trench-type PIP capacitor 22d is similar to the one in the first embodiment. The trench-type PIP capacitor of the second embodiment can be used in this fifth embodiment. In FIG. 5, the upper right part continues to the lower left part as indicated by the line with an arrow. This is applicable to all the drawings from FIGS. 6 through 10.

The power IC of FIG. 5 comprises a semiconductor substrate composed of n⁺-type semiconductor layer 2 and n⁻-type epitaxial layer 3 formed on n⁺-type semiconductor layer 2, vertical power MOSFET 21 with a trench gate structure, lateral MOSFET 22a of a planar gate structure composing a control circuit, and trench-type PIP capacitor 22d, which is the same as trench-type PIP capacitor 50 of FIG. 1. Edge termination structure 23 is formed at the end region of vertical power MOSFET 21 with a trench gate structure. Trench 35a for forming the gate of vertical MOSFET 21 is formed simultaneously with trench 35b of trench-type PIP capacitor 22d, to reduce the manufacturing cost.

Vertical power MOSFET 21 with a trench gate structure has a trench gate structure in which gate oxide film 7a is formed on the inner wall of trench 35a and polysilicon 6a for gate electrode is embedded in the trench through gate oxide film 7a. MOSFET 21 comprises p-type channel region 5, n⁺-type source region 9a disposed in the surface region of p-type channel region 5, and high concentration p⁺-type contact region 10 that is connected to p-type channel region 5 and deeper than n⁺-type source region 9a.

N⁺-type source region 9a and p⁺-type contact region 10 are connected to metal layer 12f, which becomes a source terminal of vertical power MOSFET 21 with a trench gate structure. Metal layer 1 is formed on the rear surface of the semiconductor substrate. Metal layer 1 becomes a drain terminal.

Interlayer dielectric film 13a is disposed between polysilicon 6a and metal layer 12f to electrically insulate the two from each other. Edge termination structure 23 has a field plate structure that comprises oxide film 11d, polysilicon 6a formed on oxide film 11d, and metal layer 12g connected to polysilicon 6a. The field plate structure enhances breakdown voltage.

Lateral MOSFET 22a composing a control circuit comprises p⁻-type well region 4a, n⁺-type drain region 9b, n⁺-type source region 9b (the drain region and the source region are given the same symbol 9b), and p⁺-type contact region 8a. Metal layer 12a and 12b become a drain terminal and a source terminal, respectively. Metal layer 12c is a back gate terminal connected to p⁺ contact region 8a. Polysilicon 6a becomes a gate terminal.

Trench-type PIP capacitor 22d, which is the same as trench-type PIP capacitor 50 in FIG. 1, has the structure described below. A lower electrode is polysilicon 6c, which is the same as first polysilicon 54 in FIG. 1, embedded in trench 35b. On the lower electrode capacitive insulation layer 15 is disposed, which is the same as capacitive insulation layer 55 in FIG. 1. On capacitive insulation layer 15, an upper electrode of polysilicon 14, which is the same as second polysilicon 56 in FIG. 1, is disposed.

Oxide film 6d is disposed between the lower electrode of polysilicon 6c and n⁻-type epitaxial layer 3, to electrically insulate trench-type PIP capacitor 22d from n⁻-type epitaxial layer 3. Oxide film 6d corresponds to isolating insulation layer 53 in FIG. 1. Metal layer 12e is disposed on interlayer dielectric film 13b and electrically connects the upper electrode of polysilicon 14 to other circuit elements of the control circuit.

The surface height of polysilicon 6c is made equal to the surface height of n⁻-type epitaxial layer 3. This configuration is achieved by etching polysilicon 6c deposited on the whole surface using n⁻-type epitaxial layer 3 as a stopper for the etching process.

As described previously with reference to FIG. 1A, the lower electrode of polysilicon 6c leads out to the surface along the end side wall of trench 35b extending in the direction perpendicular to the page of FIG. 5. The lower electrode of polysilicon 6c is then connected to metal layer 12g, for example, and metal layer 12g is in turn electrically connected to another semiconductor element.

Between lateral type MOSFET 22a and trench-type PIP capacitor 22d an oxide film 11a is formed, which is a LOCOS and works as an element-isolating region.

Although not illustrated here, other LOCOS oxide films 11b and 11c are formed to work as an element-isolating region between circuit elements, for example, a lateral type MOSFET composing a control circuit.

Step 32a at end part 32 of trench-type PIP capacitor 22d according to the invention, having the lower electrode of polysilicon 6c embedded within trench 35b, is smaller than step 31a at end part 31 of the traditional planar-type PIP capacitor 22c shown in FIG. 10 by the thickness of polysilicon 6c of capacitor 22c.

Specific numerical consideration is made in the following for the case in which: a thickness of lower polysilicon 6c of trench-type PIP capacitor 22d (FIG. 5) and lower polysilicon 6c of planar-type PIP capacitor 22c (FIG. 10) are both 0.5 μm, a thickness of the capacitive insulation layer 15 is 0.025 μm, and a thickness of the upper polysilicon 14 is 0.25 μm. These are only examples and the thicknesses are not limited to these values.

Because trench-type PIP capacitor 22d of FIG. 5 has a surface height, the level of the top plane, of lower polysilicon 6c equal to the surface height of the surrounding n⁻-type epitaxial layer 3, step 32a is the sum of the thickness of capacitive insulation layer 15 and the thickness of upper polysilicon 14, the sum being equal to the thickness T4 indicated in FIG. 1, and is 0.025 μm+0.25 μm=0.275 μm.

Step 31a of planar-type PIP capacitor 22c has a thickness of the sum of thicknesses of polysilicon 6c at the bottom, capacitive insulation layer 15, and polysilicon 14 at the top, and is 0.5 μm+0.025 μm+0.25 μm=0.775 μm. Thus, step 32a of trench-type PIP capacitor 22d can be reduced by 0.5 μm, which is the thickness of bottom polysilicon 6c, as compared with step 31a of planar-type PIP capacitor 22c.

Thus, metallic layer 12e for wiring does not need to be excessively thick and a special flattening treatment such as CMP is unnecessary. As a result, obstacles to fine circuit structure are removed while suppressing the rise of manufacturing costs.

In the process of forming trench-type PIP capacitor 22d, integration with general IC processes is easily accomplished by using capacitive insulation layer 15 of a silicon oxide film between an upper electrode of polysilicon 14 and a lower electrode of polysilicon 6c. The silicon oxide film can be formed by a CVD (chemical vapor deposition) method, without adding thermal history that might change the performances of other semiconductor elements.

Reduction of steps is possible by fabricating simultaneously trench 35a of vertical power MOSFET 21, which is an output stage semiconductor element, and trench 35b of trench-type PIP capacitor 22d. Thus the manufacturing cost can be reduced.

Power ICs are generally used by applying a high voltage to output stage semiconductor elements. In such a case, n⁻-type epitaxial layer 3, which is at the same potential as the drain terminal of vertical power MOSFET 21 having a trench gate structure, is at a high voltage. When the lower electrode of polysilicon 6c is used at a low potential under this condition, a high voltage is applied between n⁻-type epitaxial layer 3 and lower side polysilicon 6c. Therefore, oxide film 6d is necessarily formed thick to avoid breakdown of the film. When oxide film 6d is made thick, however, the trench width, which is a dimension of the opening of the trench, needs to be broadened corresponding to the increased thickness of oxide film 6d. That is an obstacle against promotion of fine structure of power ICs. When oxide film 6d is not made thick, on the other hand, a high voltage must not be applied between n⁻-type epitaxial layer 3 and the lower electrode of polysilicon 6c. This requires a circuit design that avoids a low voltage of the lower electrode of polysilicon 6c. This is a constraint on the circuit design.

The next embodiment describes a method for reducing a voltage applied between n⁻-type epitaxial layer 3 and polysilicon 6c.

### Sixth Embodiment

FIG. 6 is a sectional view of an essential part of a power integrated circuit device of a sixth embodiment according to the present invention. The structure of FIG. 6 differs from that of FIG. 5 in that p-type diffusion layer 18 (corresponding to the diffusion layer 61 in FIG. 3) is formed in the surface region of n⁻-type epitaxial layer 3; trench 35b is formed in the surface region of p-type diffusion layer 18; and a lower electrode of polysilicon 6c is embedded in trench 35b through oxide film 6d. Thus, trench 35b is enclosed in p-type diffusion layer 18.

When a high voltage is applied between n⁻-type epitaxial layer 3 and polysilicon 6c for the lower electrode, pn junction 18a between p-type diffusion layer 18 and n⁻-epitaxial layer 3 is biased in reverse, extending a depletion layer from pn junction 18a. Thus, the applied voltage is partly borne by pn junction 18a to mitigate the electric field applied on oxide film 6d. Thus, provision of p-type diffusion layer 18 avoids breakdown of oxide film 6d without excessively increasing the thickness of oxide film 6d. Consequently, the width of trench 35b is not necessarily broadened eliminating an obstruction against fine structure of a power IC.

Provision of p-type diffusion layer 18 allows the voltage of the lower electrode of polysilicon 6c to be freely set, irrespective of the potential of n⁻-type epitaxial layer 3, increasing freedom of circuit design.

When trench-type PIP capacitor 65 of Second Embodiment is applied, step 32a is further decreased to make a power IC finer.

### Seventh Embodiment

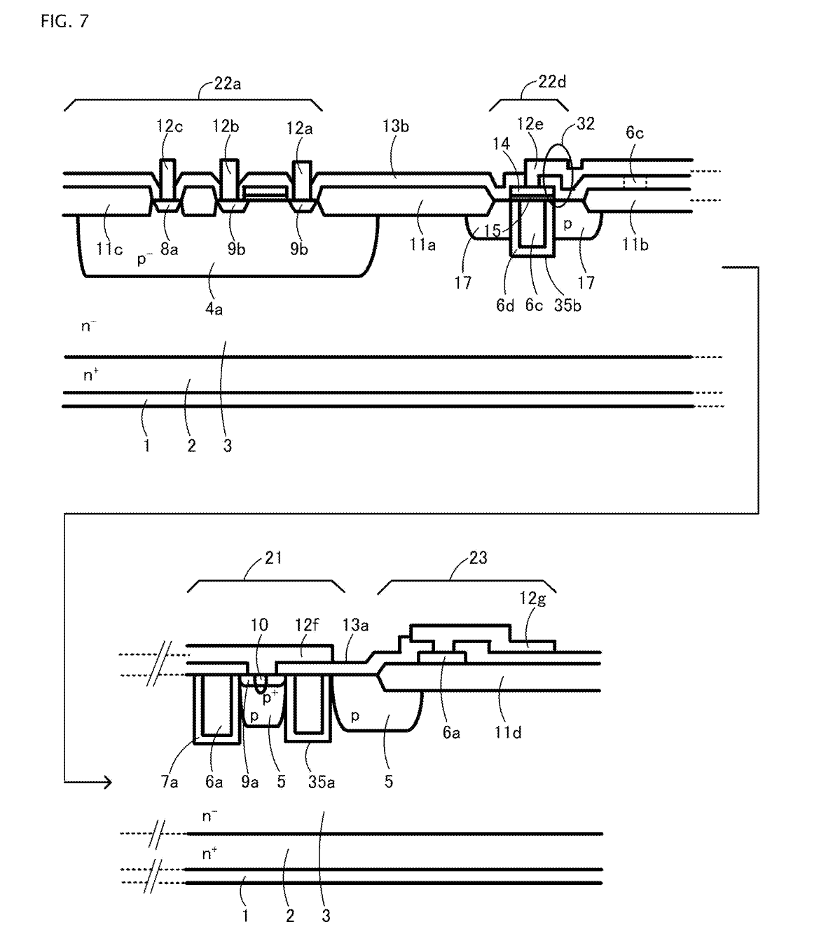

FIG. 7 is a sectional view of an essential part of a power integrated circuit device of a seventh embodiment according to the present invention. This device of FIG. 7 differs from the device of FIG. 6 in that trench 35b passes through p-type diffusion layer 17 reaching n⁻-type epitaxial layer 3. This structure allows simultaneously forming trench 35a of vertical power MOSFEET 21 with a trench gate structure and trench 35b of trench-type PIP capacitor 22d, and also allows simultaneously forming p-type channel region 5 and p-type diffusion layer 17, reducing manufacturing cost. This configuration in which p-type diffusion layer 17 does not completely cover trench 35b also works for electric field relaxation.

When trench-type PIP capacitor 65 of Second Embodiment is applied, step 32a is further reduced to make a power IC finer.

### Eighth Embodiment

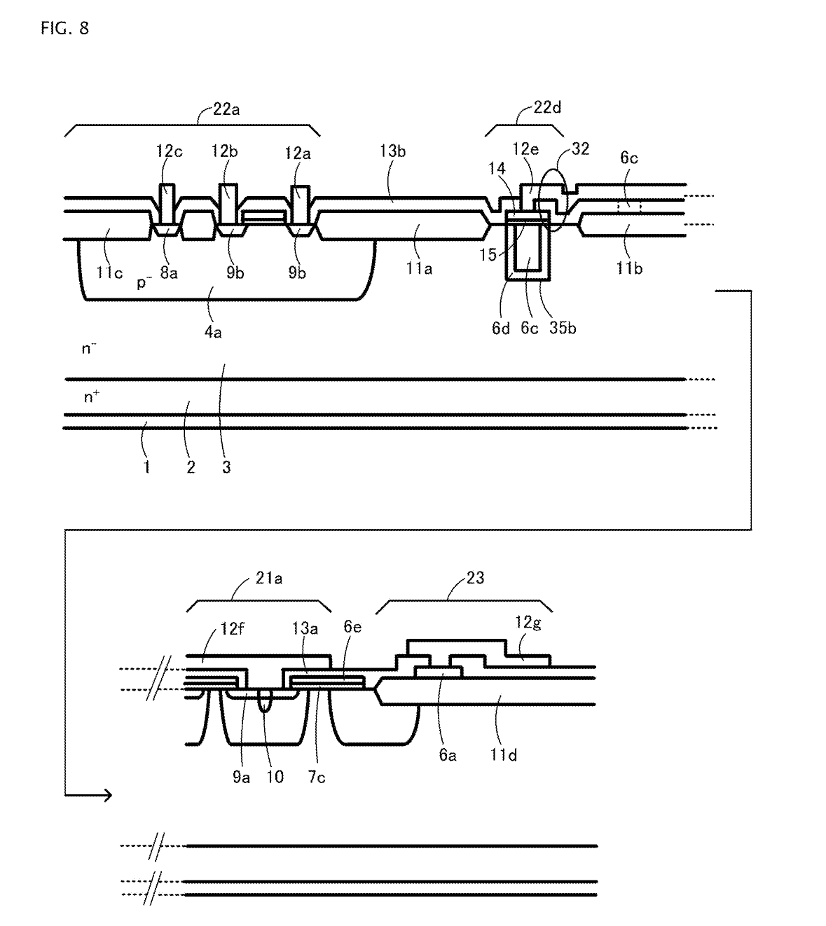

FIG. 8 is a sectional view of an essential part of a power integrated circuit device of an eighth embodiment according to the invention. This device of FIG. 8 differs from the device of FIG. 5 in that vertical power MOSFET 21 with a trench gate structure is replaced by vertical power MOSFET 21a with a planar gate structure. The trench-type PIP capacitor can also be applied to the power IC having a vertical power MOSFET with a planar gate structure to achieve fine structure of a power IC while suppressing increase in manufacturing costs. Although the Eighth Embodiment is described in application of the trench-type PIP capacitor 50 of the First Embodiment, other structures can be applied including: the trench-type PIP capacitor 65 of Second Embodiment, and the structures having diffusion layers 61 or 63 in Third and Fourth Embodiments. These embodiments also provide the same effects described previously.

Thus, a trench-type pip capacitor, power integrated circuit device using the capacitor, and method of manufacturing the power integrated circuit device have been described according to the present invention. Many modifications and variations may be made to the techniques and structures described and illustrated herein without departing from the spirit and scope of the invention. Accordingly, it should be understood that the devices and methods described herein are illustrative only and are not limiting upon the scope of the invention.

### DESCRIPTION OF SYMBOLS

1, 12a, 12b, 12c, 12d, 12e, 12f, 12g, 59: metal layer
2: n⁺-type semiconductor layer
3: n⁻-type epitaxial layer
4a: p⁻-type well region
5: p-type channel region
6a, 6b, 6c: polysilicon
6d: oxide film
7a: gate oxide film
7c, 15: capacitive insulation layer
8a, 10: p⁺-type contact region
9a: n⁺-type source region
9b: n⁺-type drain region/n+ type source region
11a, 11b, 11c, 11d: LOCOS oxide film
13a, 13b, 57: interlayer dielectric film
14: polysilicon
16: semiconductor layer
17, 18: p-type diffusion layer
21: vertical power MOSFET with a trench gate structure
21a: vertical power MOSFET with a planar gate structure
22a: lateral MOSFET
22b: MOS capacitor
22c: planar-type PIP capacitor
22d, 50, 65: trench-type PIP capacitor
23: edge termination structure
31, 32, 66: end part
31a, 32a, 60: step
35a, 35b, 52: trench
51: semiconductor substrate
53: isolating insulation layer
54: first polysilicon
55: capacitive insulation layer
56: second polysilicon
58: contact hole
61, 63: diffusion layer
18a, 62, 64: pn junction
101: high-side type power IC
102: output stage semiconductor element
103: power supply terminal
104: input terminal
105: output terminal
106: ground terminal
107: control circuit
111: logic circuit
112: driving circuit
113: protecting circuit
120: charge pumping circuit

What is claimed is:

1. A trench-type PIP capacitor comprising:
a trench that is formed from a surface of a semiconductor layer toward an inner part of the semiconductor layer;
an isolating insulation layer that is formed on an inner wall of the trench:
a lower electrode comprising a first polysilicon filled in the trench, the isolating insulation layer electrically isolating the first polysilicon from the semiconductor layer;
a capacitor comprising a capacitive insulation layer formed on the first polysilicon; and
an upper electrode comprising a second polysilicon that is formed on the capacitive insulation layer.

2. The trench-type PIP capacitor according to claim 1, wherein the height of the surface of the first polysilicon is substantially equal to the height of the surface of the semiconductor layer.

3. A power integrated circuit device comprising the trench-type PIP capacitor according to claim 1, an output stage element that passes or interrupts main current, and a control circuit for controlling the output stage element, the latter two components being formed on the same semiconductor layer on which the trench-type PIP capacitor is formed.

4. The power integrated circuit device according to claim 3, wherein a well region of a conductivity type different from that of the semiconductor layer is formed selectively in the surface region of the semiconductor layer, and the trench-type PIP capacitor is formed in the well region.

5. The power integrated circuit device according to claim 3, wherein a well region of a conductivity type different from that of the semiconductor layer is formed selectively in the surface region of the semiconductor layer, and the trench-type PIP capacitor is formed passing through the well region.

6. The power integrated circuit device according to claim 4, wherein the well region is a diffusion layer.

7. The power integrated circuit device according to claim 3, wherein the semiconductor layer is an epitaxial layer formed on a semiconductor base material that has an impurity concentration higher than that of the semiconductor layer.

8. The power integrated circuit device according to claim 3, wherein the control circuit includes a charge pumping circuit that uses the trench-type PIP capacitor as a capacitor in the charge pumping circuit.

9. The power integrated circuit device according to claim 3, wherein the output stage element is a vertical power MOS semiconductor element with a trench gate structure or a planar gate structure.

10. The trench-type PIP capacitor according to claim 1, wherein a well region of a conductivity type different from that of the semiconductor layer is formed selectively in the surface region of the semiconductor layer, and the trench-type PIP capacitor is formed in the well region.

11. The trench-type PIP capacitor according to claim 1, wherein a well region of a conductivity type different from that of the semiconductor layer is formed selectively in the surface region of the semiconductor layer, and the trench-type PIP capacitor is formed passing through the well region.

12. The trench-type PIP capacitor according to claim 1, wherein the height of the surface of the second polysilicon is substantially equal to the height of the surface of the semiconductor layer.

13. A power integrated circuit device comprising the trench-type PIP capacitor defined by claim 12, an output stage element that passes or interrupts main current, and a control circuit for controlling the output stage element, the latter two components being formed on the same semiconductor layer on which the trench-type PIP capacitor is formed.

14. The power integrated circuit device according to claim 13, wherein a well region of a conductivity type different from that of the semiconductor layer is formed selectively in the surface region of the semiconductor layer, and the trench-type PIP capacitor is formed in the well region.

15. The power integrated circuit device according to claim 13, wherein a well region of a conductivity type different from that of the semiconductor layer is formed selectively in the surface region of the semiconductor layer, and the trench-type PIP capacitor is formed passing through the well region.

16. The power integrated circuit device according to claim 14, wherein the well region is a diffusion layer.

17. The power integrated circuit device according to claim 13, wherein the semiconductor layer is an epitaxial layer formed on a semiconductor base material with an impurity concentration higher than that of the semiconductor layer.

18. The power integrated circuit device according to claim 13, wherein the control circuit includes a charge pumping circuit that uses the trench-type PIP capacitor for a capacitor in the charge pumping circuit.

19. The power integrated circuit device according to claim 13, wherein the output stage element is a vertical power MOS semiconductor element with a trench gate structure or a planar gate structure.

20. The power integrated circuit device according to claim 5, wherein the well region is a diffusion layer.

21. The power integrated circuit device according to claim 15, wherein the well region is a diffusion layer.

22. A method of manufacturing a power integrated circuit device, comprising:
forming a trench from a surface of a semiconductor layer toward an inner part of the semiconductor layer;
forming an isolating insulation layer on an inner wall of the trench:
forming a lower electrode comprising a first polysilicon filled in the trench, the isolating insulation layer electrically isolating the first polysilicon from the semiconductor layer;
forming a capacitor comprising a capacitive insulation layer formed on the first polysilicon;
forming an upper electrode comprising a second polysilicon that is formed on the capacitive insulation layer; and
forming an output stage element which is a vertical power MOS semiconductor element with a trench gate structure,
wherein the trench to be filled with the first polysilicon is formed simultaneously with a trench to deposit a gate of the vertical power MOS semiconductor element with the trench gate structure.

23. A method of manufacturing a power integrated circuit device comprising:
(i) forming a trench-type PIP-type capacitor by:
forming a trench from a surface of a semiconductor layer toward an inner part of the semiconductor layer;
forming an isolating insulation layer on an inner wall of the trench:
forming a lower electrode comprising a first polysilicon filled in the trench, the isolating insulation layer electrically isolating the first polysilicon from the semiconductor layer;
forming a capacitor comprising a capacitive insulation layer formed on the first polysilicon; and
forming an upper electrode comprising a second polysilicon that is formed on the capacitive insulation layer; and
(ii) forming an output stage element that passes or interrupts main current and a control circuit for controlling the output stage element, the latter two components being formed on the same semiconductor layer on which the trench-type PIP capacitor is formed,
wherein the capacitive insulation layer is a silicon oxide film formed by a chemical vapor deposition (CVD) method.
